(19) United States
(12) Patent Application Publication
(10) Pub. No.: US 2011/0117752 A1
(43) Pub. Date: May 19, 2011

(54) METHOD AND SYSTEM FOR ETCHING A SILICON DIOXIDE FILM USING DENSIFIED CARBON DIOXIDE

(76) Inventors: Kwon Taek Lim, Busan (KR); Jae Hyeon Bae, Busan (KR)

(21) Appl. No.: 12/621,140

(22) Filed: Nov. 18, 2009

(51) Int. Cl. H01L 21/306

(52) U.S. Cl. 438/756; 156/345.15; 257/E21.219

(57) ABSTRACT

The present invention relates to a method and system for removing a sacrificial layer from an MEMS structure or from any other semiconductor substrate that includes a sacrificial layer. The above etching method and system use densified carbon dioxide, fluorine compounds, and co-solvents as the processing fluid and are capable of removing the sacrificial layer in a short period of time without incurring damage on the structural layer or incurring stiction between structures. In addition, the above etching method and system do not create etching residue and thus do not require a separate cleaning process.

### BACKGROUND

1. Technical Field

The present invention relates to a method and system of using supercritical carbon dioxide for removing a silicon dioxide film, which is used as a sacrificial layer in the manufacture of MEMS (micro-electro-mechanical systems) and DRAM (dynamic random access memory) capacitors.

2. Description of the Related Art

An MEMS is a device that combines mechanical and electrical components on a single silicon wafer, where the mechanical and electrical components may be fabricated using conventional integrated circuit (IC) methods and micromachining processes. The mechanical components on an MEMS wafer may be manufactured by depositing a sacrificial layer and a structural layer on the substrate, followed by selectively etching the sacrificial layer in relation to the structural layer, so that suspended or freestanding structures such as beams and levers may remain. The processes for manufacturing MEMS and DRAM capacitors generally employ wet etching processes which utilize hydrofluoric acid (HF). A major problem, however, in fabricating MEMS structures is stiction, which may occur during the etching of the sacrificial layer. The causes of such stiction include, for example, van der Waals forces, hydrogen bridging, electrostatic attractions between the microstructures and the substrate, surface tension forces created by the menisci of the liquid trapped in the etched spaces, and etching by-products precipitated from the solution during the drying phase. As described above, the degree of surface tension of the solvent used in fabricating the microstructure (especially during the etching of the sacrificial layer) has a large impact on the damage incurred on the microstructures. In attempt to resolve this problem, methods of minimizing surface tension energy, such as by increasing surface roughness or by drying the structure with liquids (e.g. isopropanol (IPA)) that have zero or almost zero surface tension, have been applied to existing wet etching methods based on hydrofluoric acid, and several methods have been proposed for minimizing stiction.

Among the proposed methods, the method of utilizing supercritical fluids, which have zero surface tension, is known to be the best. FIG. 6 is a phase diagram of carbon dioxide. At above the critical temperature, regardless of changes in pressure, a substance attains a single-phase supercritical state, in which there is no distinction between the gas and liquid phases, as illustrated in FIG. 6. The point of minimum temperature and pressure at which this supercritical state begins is referred to as the critical point. In contrast to typical liquid solvents, the physical properties, such as density, viscosity, diffusivity, polarity, etc., of a substance in a supercritical state (hereinafter referred to as “supercritical fluid”) can be varied, according to changes in pressure, in a continuous manner from a liquid-like state to a gas-like state. The supercritical fluid provides high solvency, high diffusivity, low viscosity, and low surface tension. In particular, carbon dioxide, which has a critical temperature and critical pressure of only 31.1° C. and 73.8 atm, respectively, is the focus of much attention in fields related to the manufacture of semiconductor devices, for instance, due to its non-toxic and non-inflammable characteristics and inexpensive cost. By using supercritical carbon dioxide, which has zero surface tension, as the solvent when etching a silicon dioxide film, stiction can be avoided completely.

However, since supercritical carbon dioxide fluid has solubility characteristics similar to non-polar organic solvents, there may be dissolving selectivity when it is used alone. As such, the use of supercritical carbon dioxide fluid is not sufficient for etching and removing a silicon dioxide film, i.e. the sacrificial layer. Thus, there has been much research geared towards etching a silicon dioxide film in a supercritical state by adding an additive that is effective in etching and removing particles of the sacrificial layer, such as an anhydrous fluorine compound, etc., capable of etching a silicon dioxide film, to the supercritical carbon dioxide fluid.

However, the etching of a silicon dioxide film using an anhydrous fluorine compound in densified carbon dioxide, etc., may entail the problem of etching residues, which does not occur when employing wet etching. For example, when etching is performed in a supercritical carbon dioxide environment using a mixture of hydrofluoric acid and pyridine as the etchant, white etching residues may remain on the surface of the wafer, in contrast to etching in an aqueous hydrofluoric acid solution. Thus, an additional cleaning process for removing the etching residues from the surface may be required, and as the etching residues are known to be insoluble in most organic solvents other than water, there may be great difficulty involved in cleansing. Efforts aimed at removing the etching residues include research on cleaning methods using organic compounds and surfactants, etc.

In this context, the inventors have researched a method and system for etching a silicon dioxide film in densified carbon dioxide. Densified carbon dioxide including fluorine compounds and deionized water is used to etch the silicon dioxide film, i.e. the sacrificial layer, in short time without damaging the microstructures and without stiction. The occurrence of etching residues, which may otherwise occur during the dry etching process in densified carbon dioxide, can be avoided, obviating the need for a separate cleaning process.

### SUMMARY

One aspect of the invention provides a method for etching a silicon dioxide film using densified carbon dioxide. The method includes: supplying a semiconductor substrate into a processing chamber from the outside for the purpose of forming a structure; etching a sacrificial layer by supplying densified carbon dioxide and injecting an etchant into the processing chamber; removing fluids from the processing chamber by way of pure densified carbon dioxide after the etching is finished; and drying the substrate by lowering the pressure within the processing chamber.

Here, the structure can include any one of an MEMS (micro-electro-mechanical system) structure, an NEMS (nano-electro-mechanical system) structure, and a DRAM (dynamic random access memory) cell.

The etchant can include a fluorine compound and a co-solvent that necessarily includes deionized water. The fluorine compound may include any one of hydrofluoric acid (HF), hydrofluoroether (HFE), poly-4-vinylpyridinium poly(hydrogen fluoride), hydrogen fluoride 2,4,6-trimethylpyridine, and ammonium fluoride (NH₄F).

The deionized water can be used within a range of 0.001 to 10 weight % of a carbon dioxide solvent. The etchant can be used within a range of 0.001 to 10 weight % dissolved in carbon dioxide.

The co-solvent includes any one of methanol, ethanol, isopropyl alcohol (IPA), and butanol. The densified carbon dioxide may include liquid carbon dioxide and supercritical carbon dioxide within a temperature range of 20 to 100° C. and a pressure range of 800 to 5000 psi.

The sacrificial layer can include any one of tetraethyl orthosilicate (TEOS), phosphosilicate glass (PSG), borosilicate glass (BSG), borophosphosilicate glass (BPSG), and thermal SiO₂.

Another aspect of the invention provides a system for etching a silicon dioxide film using densified carbon dioxide. The system includes: a processing chamber, into which a semiconductor substrate having a silicon dioxide film may be loaded; an etchant storage tank for supplying an etchant to the processing chamber; an injection pump for injecting the etchant into the processing chamber; a carbon dioxide storage tank that provides carbon dioxide; a syringe pump that pressurizes the carbon dioxide into densified carbon dioxide and supplies the densified carbon dioxide to the processing chamber; an outlet through which a solution used in etching may be discharged from the processing chamber; and a regulator apparatus that controls the temperature within the processing chamber and regulates mixing.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flow diagram illustrating a method for etching a silicon dioxide film using densified carbon dioxide.

FIG. 2 is a schematic diagram illustrating a system for etching a silicon dioxide film using densified carbon dioxide.

FIG. 3 is an electron microscope image for comparing a mode of etching a sacrificial layer according to an embodiment of the invention with a mode of etching a sacrificial layer according to an existing wet etching method.

FIG. 4 is an electron microscope image for comparing the effect of etching a silicon dioxide film using an anhydrous fluorine compound with the effect of using an embodiment of the invention.

FIG. 5 is an electron microscope image illustrating the effect of an etching method according to an embodiment of the invention.

FIG. 6 is a phase diagram of carbon dioxide.

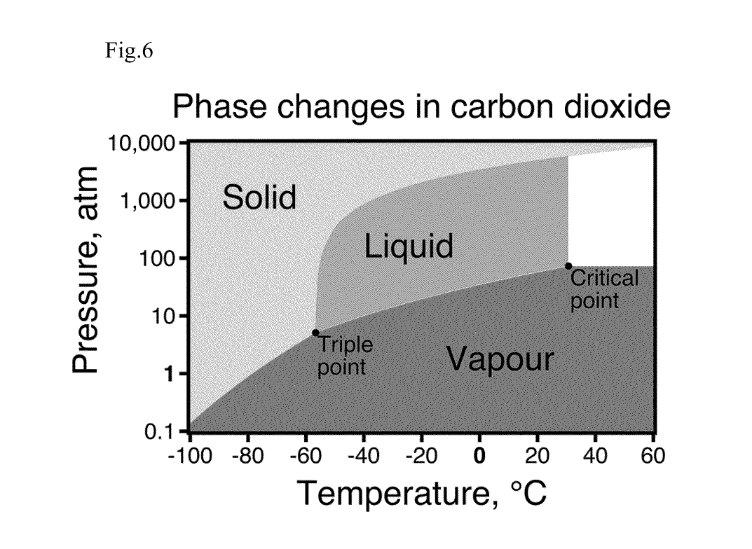

### DETAILED DESCRIPTION

A feature of the present invention is to use an etchant made by adding a fluorine compound and a co-solvent to densified carbon dioxide. This can greatly increase the etching rate of a silicon dioxide film in a high-pressure etching system and does not leave behind etching residues after the etching, even without a separate cleaning process.

An aspect of the invention includes the development of an etchant that utilizes densified carbon dioxide. After etching the silicon dioxide film using a system including a high-pressure chamber and the above etchant, the etchant may be removed using pure densified carbon dioxide.

According to an aspect of the invention, the operation of etching the silicon dioxide film and the operation of removing the etchant may be performed continuously, under conditions close to the critical point of carbon dioxide. The conditions for removing the silicon dioxide film and removing the etchant can include a temperature range of 20 to 100° C. and a pressure range of 800 to 5000 psi.

In certain embodiments of the invention, the silicon dioxide film can be one of a tetraethyl orthosilicate (TEOS) film, a phosphosilicate glass (PSG) film, a borosilicate glass (BSG) film, a borophosphosilicate glass (BPSG) film, and a thermal SiO₂ film, used as a sacrificial layer for forming a structure by MEMS manufacturing.

The fluorine compound can be any one of hydrofluoric acid (HF), hydrofluoroether (HFE), poly-4-vinylpyridinium poly(hydrogen fluoride), hydrogen fluoride 2,4,6-trimethylpyridine, and ammonium fluoride (NH₄F).

The co-solvent necessarily includes deionized water, and can be used within a range of 0.001 to 10 weight % of the densified carbon dioxide solvent. In certain preferred examples, the range can be between 0.01 to 1 weight %. More preferably, an appropriate amount may be used by which a completely uniform solution can be made with the densified carbon dioxide, under the given temperature and pressure conditions. For example, if the densified carbon dioxide is at 40° C. and 2900 psi, the deionized water can be used up to a maximum of 0.025 weight % to form a completely uniform solution.

If the amount of deionized water included in the co-solvent exceeds the amount that is soluble in the densified carbon dioxide under the given temperature and pressure conditions, an operation of removing fluids from the processing chamber, described later, can be regulated to remove the excess deionized water. That is, if the amount of deionized water used is greater than the amount that makes a uniform solution with the densified carbon dioxide, the deionized water may be completely removed from the processing chamber after the reactions are complete, by removing the phase-separated co-solvent from the processing chamber followed by sufficiently rinsing the processing chamber with pure densified carbon dioxide, before the operation of lowering the pressure inside the processing chamber to dry the substrate.

The co-solvent can include alcohol, which may be one of methanol, ethanol, isopropyl alcohol (IPA), and butanol.

In an embodiment of the invention, an operation of etching the silicon dioxide film can utilize the densified carbon dioxide in which a mixture of the fluorine compound and the co-solvent is dissolved in 0.001 to 10 weight %.

More detailed descriptions will be provided below with reference to the appended drawings.

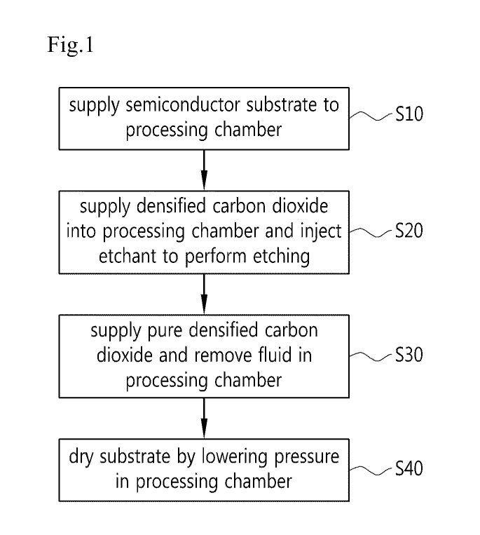

FIG. 1 is a flow diagram illustrating a method for etching a silicon dioxide film using densified carbon dioxide. Referring to FIG. 1, the silicon dioxide film etching process may proceed as follows. A semiconductor substrate may be supplied from outside to a processing chamber (S10). Next, to carbon dioxide being supplied to the processing chamber from a carbon dioxide storage tank, a syringe pump may apply pressure and thus produce densified carbon dioxide, which may then be supplied to the processing chamber by way of a three-way valve. At the same time, an etchant from an etchant storage tank may be injected into the processing chamber using an injection pump. With the injection of the densified carbon dioxide and the etchant, the etching of the silicon dioxide film may proceed within the processing chamber, while a regulator apparatus may be used to maintain a constant internal environment within the processing chamber in terms of temperature and mixing. In order to remove the mixture of the densified carbon dioxide and the etchant from the processing chamber when the etching of the silicon dioxide film is complete, pure densified carbon dioxide may be supplied from the syringe pump, while the fluid may be discharged past a two-way valve and through an outlet, and in this manner, the mixture can be removed from the processing chamber. To dry the substrate within the processing chamber, the supply of the densified carbon dioxide and the etchant solution can be stopped by closing the three-way valve, and the fluid inside the processing chamber can be discharged by opening a two-way valve, i.e. a discharge valve, through an outlet.

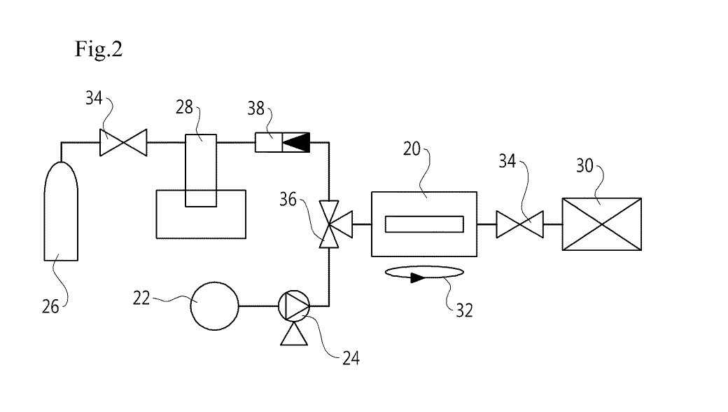

FIG. 2 is a schematic diagram illustrating a system for etching a silicon dioxide film using densified carbon dioxide. The system shown in FIG. 2 is an example of a high-pressure chamber system capable of performing etching under conditions above the critical point of a solvent, as provided by an aspect of the invention.

Referring to FIG. 2, a system according to an embodiment of the invention may include a processing chamber 20, into which a substrate having a silicon dioxide film formed thereon may be loaded; an etchant storage tank 22 and an injection pump 24 for supplying an etchant to the processing chamber 20; a carbon dioxide storage tank 26 for providing carbon dioxide and a syringe pump 28 for forming a supercritical fluid; an outlet 30 that discharges used fluid from the processing chamber 20; and a regulator apparatus 32 that controls the temperature and regulates the mixing inside the processing chamber 20. In a system according to an embodiment of the invention, the flow of the fluid may be regulated by various two-way valves 34, three-way valves 36, and double-check valves 38. In an operation of etching the silicon dioxide film according to an embodiment of the invention, the fluid may contain the etchant and the densified carbon dioxide solvent.

Detailed descriptions will now be provided with reference to the following comparative examples.

### Comparative Example 1

To observe the effects of the present invention, a Sample Wafer 1 was used that carries a polysilicon structure having the form of cantilever beams, where a p-TEOS film having a thickness of 500 nm, used as the sacrificial layer, is located between the polysilicon beams and the substrate. The thickness of the polysilicon beams is 300 nm, and in order to investigate the stiction phenomenon according to the length of a beam, a total of 15 beams were included, ranging from 1.25 μm to 18.75 length μm in intervals of 1.25 μm.

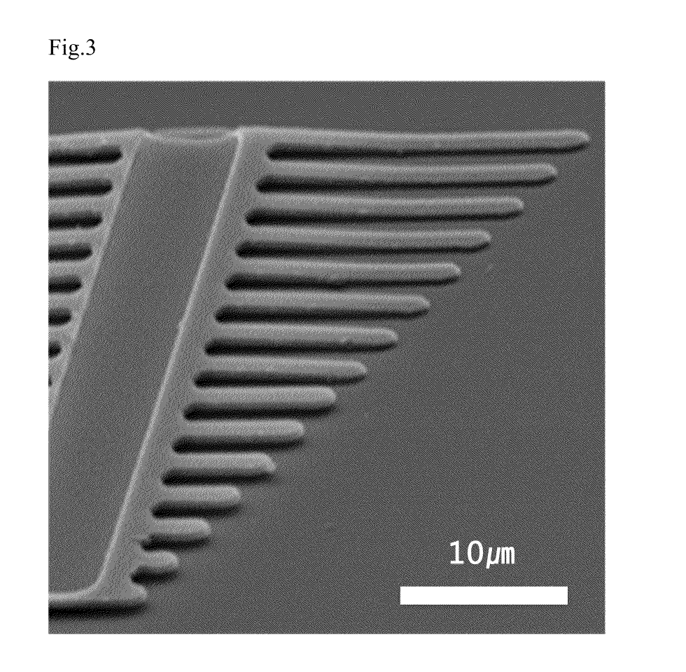

The Sample Wafer 1 was etched for 30 minutes at 50° C. by a conventional wet etching process using an aqueous hydrofluoric acid solution until the p-TEOS film used as the sacrificial layer was completely removed. As a result, the polysilicon beams of 8.75 μm or shorter did not adhere to the substrate, and the space where the p-TEOS film used to be remained empty, but for the polysilicon beams of 10 μm or longer, stiction occurred. These results can be observed from FIG. 3.

### Comparative Example 2

Etching was performed on a silicon dioxide film using densified carbon dioxide and an anhydrous fluorine compound as the etchant. The anhydrous fluorine compound was a mixture of hydrofluoric acid (HF) and pyridine, dissolved in 0.001 to 10 weight % in supercritical carbon dioxide, and the etchant was applied to the Sample Wafer 1 described above. To remove the p-TEOS film of the Sample Wafer 1, the high-pressure etching system of FIG. 2 was used.

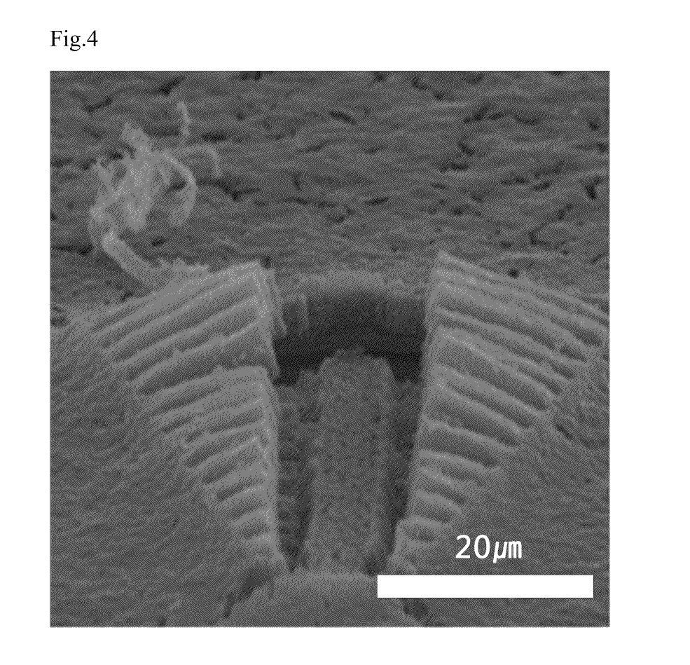

The Sample Wafer 1 was placed in the processing chamber 20 (S10), and carbon dioxide from the carbon dioxide storage tank 26 was supplied to the syringe pump 28 and pressurized to 4000 psi. To prepare the etchant, hydrofluoric acid and pyridine, mixed together in a ratio of 1:5, were dissolved in 1 weight % in the pressurized supercritical carbon dioxide and injected into the processing chamber 20 by way of the injection pump 24. Using a temperature and mixing regulator apparatus 32, the processing chamber 20 was maintained at 50° C. and mixing was performed continuously (S20). The etching operation was performed for 20 minutes, and the Sample Wafer within the processing chamber 20 had its p-TEOS film completely removed. In order to remove the supercritical fluid in the processing chamber, the three-way valve 36 between the syringe pump 28 and the processing chamber 20 as well as the two-way valve 34 were regulated such that the supercritical carbon dioxide is directed from the syringe pump 28 through the processing chamber 20 and discharged through an outlet (S30). This operation of removing the etchant was performed for 5 minutes at a flow rate of 5 ml/min to completely remove the etchant from the processing chamber 20. The pure supercritical carbon dioxide remaining in the processing chamber 20 was removed, and in order to dry the Sample Wafer 1, the two-way valve 34 was opened, with the three-way valve 36 closed, to lower the pressure. The Sample Wafer 1 subject to the above mode of etching was as shown in FIG. 4. The polysilicon structure was contaminated by etching residues created during the etching operation.

Detailed descriptions will now be provided with reference to the following test examples, in order to better illustrate the spirit of the invention.

### Test Example 1

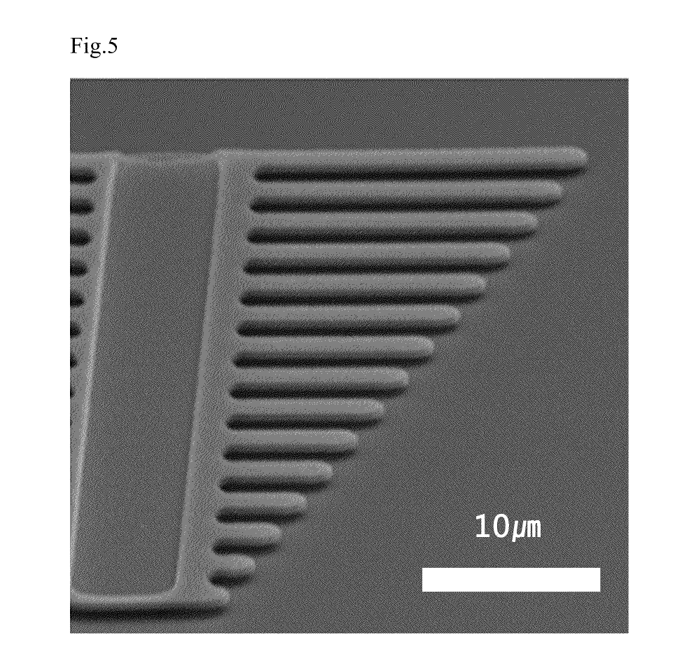

To remove the p-TEOS film of the Sample Wafer 1, an etchant using the fluorine compound and co-solvent described above according to an embodiment of the invention was used as the etchant. Specifically, the etchant was prepared by mixing hydrofluoric acid (HF) and deionized water in a ratio of 1:1. The etchant was dissolved in 0.01 to 1 weight % in supercritical carbon dioxide, and the duration for the operation (S20) of etching the sacrificial layer was changed to 10 minutes. Otherwise, the same procedures as those in Comparative Example 2 were used to perform the etching operation. The result of this etching, as shown in FIG. 5, never produces stiction in the polysilicon beam structure, even in the beams of 10 μm or longer. Moreover, there is no etching residue on the surfaces of the Sample Wafer 1, even though there was no additional cleansing operation.

### Test Example 2

Etching was performed for the Sample Wafer 1 in substantially the same manner as for Test Example 1. Here, the carbon dioxide was in a liquid state at 1000 psi and 25° C. After the above etching process was complete, the Sample Wafer 1 did not show stiction in the structure, and there was no etching residue remaining.

### Test Example 3

Etching was performed for the Sample Wafer 1 in substantially the same manner as for Test Example 1. Here, the carbon dioxide was at 1000 psi and 50° C. After the above etching process was complete, the Sample Wafer 1 did not show stiction in the structure, and there was no etching residue remaining.

### Test Example 4

Etching was performed for the Sample Wafer 1 in substantially the same manner as for Test Example 1. Here, the carbon dioxide was at 4000 psi and 25° C. After the above etching process was complete, the Sample Wafer 1 did not show stiction in the structure, and there was no etching residue remaining.

### Test Example 5

Etching was performed for the Sample Wafer 1 in substantially the same manner as for Test Example 1. Here, the etchant was prepared using hydrofluoric acid (HF) in 0.025 weight % and deionized water in 0.025 weight %, respectively, of the carbon dioxide. The carbon dioxide was at 2900 psi and 40° C., to be capable of completely dissolving the deionized water. After the above etching process was complete, the Sample Wafer 1 did not show stiction in the structure, and there was no etching residue remaining.

### Test Example 6

To remove the p-TEOS film of the Sample Wafer 1, an etchant using the fluorine compound and co-solvent described above according to an embodiment of the invention was used as the etchant. Specifically, the etchant was prepared by mixing hydrofluoric acid (HF) and deionized water in a ratio of 1:1. In etching the silicon dioxide film according to an embodiment of the invention, a pressure of 4000 psi was maintained, and the p-TEOS films of Sample Wafers 1 were removed for different temperatures of 40° C. and 100° C., using substantially the same operations as for Test Example 1. After the p-TEOS etching at 40° C. and 100° C. was complete, the Sample Wafers 1 did not show stiction in the structure, and there was no etching residue remaining.

### Test Example 7

A Sample Wafer 2 was prepared, in which the p-TEOS film for forming the polysilicon beams of the above Sample Wafer was substituted with a BPSG film. In is accordance with an embodiment of the invention, etching was performed for the silicon dioxide film in substantially the same manner as for Comparative Example 2. The etching rate for the BPSG film used as the sacrificial layer was investigated to be approximately 3 times faster than the etching rate for the p-TEOS film, so the duration of the etching operation (S20) was modified to 3 minutes. Similar to the case of Test Example 1, the polysilicon beams of Sample Wafer 2 did not show stiction in the structure after the above process was complete, even in the beams of length 10 μm or longer, and there was no etching residue remaining on any surface of the Sample Wafer 2.

The present invention as set forth above is not to be limited by the embodiments or examples described above, neither is it to be limited by the appended drawings. It will be apparent to those of ordinary skill in the art that various substitutions, additions, and modifications can be conceived without departing from the spirit and scope of the invention.

What is claimed is:

1. A method for etching a silicon dioxide film using densified carbon dioxide, the method comprising:
supplying a semiconductor substrate into a processing chamber from outside, the semiconductor substrate used for forming a structure thereon;
etching a sacrificial layer by supplying densified carbon dioxide and injecting an etchant into the processing chamber;
removing fluids from the processing chamber by way of pure densified carbon dioxide after the etching is finished; and
drying the substrate by lowering a pressure within the processing chamber.

2. The method of claim 1, wherein the structure includes any one of an MEMS (micro-electro-mechanical system) structure, an NEMS (nano-electro-mechanical system) structure, and a DRAM (dynamic random access memory) cell.

3. The method of claim 1, wherein the etchant comprises a co-solvent and a fluorine compound, the co-solvent necessarily comprising deionized water.

4. The method of claim 3, wherein the fluorine compound includes any one of hydrofluoric acid (HF), hydrofluoroether (HFE), poly-4-vinylpyridinium poly(hydrogen fluoride), hydrogen fluoride 2,4,6-trimethylpyridine, and ammonium fluoride (NH₄F).

5. The method of claim 3, wherein the deionized water is used within a range of 0.001 to 10 weight % of a carbon dioxide solvent.

6. The method of claim 3, wherein the co-solvent includes any one of methanol, ethanol, isopropyl alcohol (IPA), and butanol.

7. The method of claim 1, wherein the etchant is used within a range of 0.001 to 10 weight % dissolved in carbon dioxide.

8. The method of claim 1, wherein the densified carbon dioxide comprises liquid carbon dioxide and supercritical carbon dioxide within a temperature range of 20 to 100° C. and a pressure range of 800 to 5000 psi.

9. The method of claim 1, wherein the sacrificial layer comprises any one of tetraethyl orthosilicate (TEOS), phosphosilicate glass (PSG), borosilicate glass (BSG), borophosphosilicate glass (BPSG), and thermal SiO₂.

10. A system for etching a silicon dioxide film using densified carbon dioxide, the system comprising:
a processing chamber 20 configured to receive a semiconductor substrate loaded therein, the semiconductor substrate having a silicon dioxide film formed thereon;
an etchant storage tank 22 for supplying an etchant to the processing chamber;
an injection pump 24 for injecting the etchant into the processing chamber;
a carbon dioxide storage tank 26 providing carbon dioxide;
a syringe pump 28 configured to pressurize the carbon dioxide into densified carbon dioxide and supply the densified carbon dioxide to the processing chamber 20;
an outlet 30 configured to discharge a solution used in etching from the processing chamber 20; and
a regulator apparatus 32 configured to control a temperature within the processing chamber and regulate mixing.

11. The system of claim 10, wherein the etchant comprises a co-solvent and a fluorine compound, the co-solvent necessarily comprising deionized water.

12. The system of claim 11, wherein the fluorine compound includes any one of hydrofluoric acid (HF), hydrofluoroether (HFE), poly-4-vinylpyridinium poly(hydrogen fluoride), hydrogen fluoride 2,4,6-trimethylpyridine, and ammonium fluoride (NH₄F).

13. The system of claim 11, wherein the deionized water is used within a range of 0.001 to 10 weight % of a carbon dioxide solvent.

14. The system of claim 11, wherein the co-solvent includes any one of methanol, ethanol, isopropyl alcohol (IPA), and butanol.

15. The system of claim 10, wherein the etchant is used within a range of 0.001 to 10 weight % dissolved in carbon dioxide.

16. The system of claim 10, wherein the densified carbon dioxide comprises liquid carbon dioxide and supercritical carbon dioxide within a temperature range of 20 to 100° C. and a pressure range of 800 to 5000 psi.
